(19) United States
(12) Patent Application Publication
(10) Pub. No.: US 2025/0171923 A1
(43) Pub. Date: May 29, 2025

(54) ALUMINUM ALLOY SURFACE TREATMENT METHOD AND ALUMINUM ALLOY THEREBY

(71) Applicant: Samsung Electronics Co., Ltd., Suwon-si (KR)

(72) Inventors: Sungyoung HEO, Suwon-si (KR); Goeun KIM, Suwon-si (KR); Inkyu KIM, Suwon-si (KR); Hyunsoo KIM, Suwon-si (KR); Hyesun PARK, Suwon-si (KR); Heesung LEE, Suwon-si (KR); Youngsoo JUNG, Suwon-si (KR); Kyunghwan SONG, Suwon-si (KR); Hyunsuk CHOI, Suwon-si (KR)

(21) Appl. No.: 19/036,583

(22) Filed: Jan. 24, 2025

Related U.S. Application Data
(63) Continuation of application No. PCT/KR2023/010806, filed on Jul. 26, 2023.

(30) Foreign Application Priority Data
Jul. 26, 2022 (KR) 10-2022-0092409
Sep. 13, 2022 (KR) 10-2022-0114859

(51) Int. Cl. C25D 11/08; B24C 1/08; C25D 11/16

(52) U.S. Cl. CPC C25D 11/08; B24C 1/08; C25D 11/16

(57) ABSTRACT

A method of treating a surface of an aluminum alloy is provided. The method of treating the surface of the aluminum alloy may include processing the aluminum alloy in a designated shape, forming an irregularity physically on the surface of the aluminum alloy processed in the designated shape, immersing the aluminum alloy having the irregularity formed thereon into a phosphorous acid mixture containing phosphorous acid, sodium fluoride, and ammonium bifluoride with a designated mixing ratio, and anodizing the immersed aluminum alloy.

### CROSS-REFERENCE TO RELATED APPLICATIONS

This application is a continuation of International Application No. PCT/KR2023/010806 designating the United States, filed on Jul. 26, 2023, in the Korean Intellectual Property Receiving Office and claiming priority to Korean Patent Application Nos. 10-2022-0092409, filed on Jul. 26, 2022, and 10-2022-0114859, filed on Sep. 13, 2022, in the Korean Intellectual Property Office, the disclosures of each of which are incorporated by reference herein in their entireties.

### BACKGROUND

### Field

The disclosure relates to a method of treating a surface of an aluminum alloy, and the aluminum alloy based on the method.

### Description of Related Art

Aluminum alloy materials which have improved rigidity and corrosion-resistance by adding other ingredients rather than pure aluminum with low rigidity are widely used as outer materials of electronic devices. Among techniques for processing a surface of an aluminum alloy, an anodizing technique is a method of forming an oxide film on the aluminum alloy immersed into a specific solution by applying current with a metal (e.g., the aluminum alloy) as an anode and an auxiliary electrode as a cathode, in the specific solution containing, for example, sulfuric acid, oxalic acid, phosphoric acid, and/or chromic acid. An oxidation reaction occurs due to oxygen produced at the anode, and an oxide film having a uniform thickness is formed with strong adhesion to a material metal.

### SUMMARY

According to an example embodiment, the disclosure may provide a method of treating a surface of an aluminum alloy. The method may include: processing the aluminum alloy in a designated shape; forming an irregularity physically on the surface of the aluminum alloy processed in the designated shape; immersing the aluminum alloy having the irregularity formed thereon into a phosphorous acid mixture containing phosphorous acid, sodium fluoride, and ammonium bifluoride with a designated mixing ratio; and anodizing the immersed aluminum alloy, wherein the phosphorous acid mixture may contain 15 to 100 ml of the phosphorous acid, 3 to 20 ml of the sodium fluoride, and 1 to 10 ml of the ammonium bifluoride per 1 L of water.

According to an example embodiment, the disclosure may provide a surface-treated aluminum alloy including: an anodizing layer produced by forming an irregularity physically on a surface of an aluminum alloy, immersing the aluminum alloy having the irregularity formed thereon into a phosphorous acid mixture, and performing anodizing thereon, and which is exposed to the outside of the anodized aluminum alloy; and an aluminum alloy layer located below the anodizing layer.

According to an example embodiment, the disclosure may provide an aluminum alloy of which a surface is treated using a method including: processing the aluminum alloy in a designated shape; forming an irregularity physically on the surface of the aluminum alloy processed in the designated shape; and immersing the aluminum alloy having the irregularity formed thereon into a phosphorous acid mixture containing phosphorous acid, sodium fluoride, and ammonium bifluoride with a designated mixing ratio.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a diagram illustrating an example operation of manufacturing an anodized aluminum alloy according to various embodiments;

FIG. 2 is a flowchart illustrating an example method of manufacturing an anodized aluminum alloy according to various embodiments;

FIG. 3 is a flowchart illustrating an example method of manufacturing an anodized aluminum alloy according to various embodiments;

FIG. 4 is a diagram illustrating an example physical irregularity formed on an aluminum alloy through sand blasting according to various embodiments;

FIG. 5 is a diagram comparing a result of treating an aluminum alloy having a physical irregularity formed thereon with a phosphorous acid mixture and a result of treating it with other chemical substances according to various embodiments;

FIG. 6 is a diagram illustrating an example operation in which a physical irregularity formed on an aluminum alloy is etched by a phosphorous acid mixture according to various embodiments;

FIG. 7 is a diagram illustrating hydrophilicity of an aluminum alloy having a fine irregularity according to various embodiments;

FIG. 8 is a diagram illustrating an example water contact angle and a surface of an aluminum alloy of which the surface is treated according to various embodiments;

FIG. 9 is a diagram illustrating example fingerprint-resistance depending on a water contact angle of an aluminum alloy according to various embodiments;

FIG. 10A is a diagram comparing a surface of an aluminum alloy on which a physical irregularity is formed by sand blasting using a bead of 0.070 mm or less when the aluminum alloy is immersed into a phosphorous acid mixture and when the aluminum alloy is immersed into a phosphoric acid solution according to various embodiments;

FIG. 10B is a diagram comparing a surface of an aluminum alloy on which a physical irregularity is formed by sand blasting using a bead of 0.050 to 0.100 mm when the aluminum alloy is immersed into a phosphorous acid mixture and when the aluminum alloy is immersed into a phosphoric acid solution according to various embodiments;

FIG. 10C is a diagram comparing a surface of an aluminum alloy on which a physical irregularity is formed by sand blasting using a bead of 0.070 mm to 0.125 mm when the aluminum alloy is immersed into a phosphorous acid mixture and when the aluminum alloy is immersed into a phosphoric acid solution according to various embodiments;

FIG. 11 is a diagram comparing a surface of an aluminum alloy on which a physical irregularity is formed by sand blasting using a different bead when the aluminum alloy is immersed into a phosphorous acid mixture according to various embodiments;

FIG. 12 is a diagram comparing a surface of an aluminum alloy having a physical irregularity formed thereon when the aluminum alloy is immersed into a phosphorous acid mixture of a different temperature according to various embodiments;

FIG. 13 is a diagram comparing a surface of an aluminum alloy having a physical irregularity formed thereon when the aluminum alloy is immersed into a phosphorous acid mixture of a different concentration according to various embodiments;

FIG. 14 is a diagram comparing a surface of an aluminum alloy having a physical irregularity formed thereon when the aluminum alloy is immersed into a phosphorous acid mixture for different times according to various embodiments; and

FIG. 15 is a diagram comparing an etching amount of an aluminum alloy having a physical irregularity formed thereon when the aluminum alloy is immersed into a phosphorous acid mixture for a different time according to various embodiments.

### DETAILED DESCRIPTION

Hereinafter, various example embodiments of the disclosure will be described in greater detail with reference to the accompanying drawings so that those skilled in the art can easily implement the disclosure. However, the disclosure may be realized in various different forms and is not limited to the various example embodiments described herein. In addition, in order to clearly describe the disclosure, parts not related to the description are omitted in the drawings, and similar reference numerals are given to similar parts throughout the disclosure.

Terms used in the disclosure are described as general terms currently in use in consideration of functions mentioned in the disclosure, but may refer to various other terms depending on the intention of a technician engaged in the relevant field, precedents, emergence of new technologies, or the like. Therefore, the terms used in the disclosure shall not be interpreted simply based on the name of the term, but shall be interpreted based on the meaning of the term and the overall content of the disclosure.

In addition, the term ‘first’, ‘second’, or the like may be used to describe various components, but the components shall not be limited by these terms. The terms are used to distinguish one component from another.

Throughout the disclosure, when a part is mentioned to be “connected” to another part, this includes not only a case where it is “directly connected” but also a case where it is “electrically connected” thereto with other elements interposed therebetween. When a part is mentioned to “include” a component, this does not exclude other components, but rather that it may further include other components, unless otherwise specified.

Phrases such as “in an embodiment” and the like mentioned in various places in this disclosure do not necessarily all refer to the same embodiment.

A method of treating a surface of an aluminum alloy according to an embodiment of the disclosure may include processing the aluminum alloy in a designated shape. In addition, the method of treating the surface of the aluminum alloy may include forming an irregularity physically on the surface of the aluminum alloy processed in the designated shape. In addition, the method of treating the surface of the aluminum alloy may include immersing the aluminum alloy having the irregularity formed thereon into a phosphorous acid mixture containing phosphorous acid, sodium fluoride, and ammonium bifluoride with a designated mixing ratio. In addition, the method of treating the surface of the aluminum alloy may include anodizing the immersed aluminum alloy. In addition, the phosphorous acid mixture may contain 15 to 100 ml of the phosphorous acid, 3 to 20 ml of the sodium fluoride, and 1 to 10 ml of the ammonium bifluoride per 1 L of water.

In addition, the forming of the irregularity physically may be forming, on the processed aluminum alloy, the irregularity having a surface roughness value of Ra 2.00 μm or less and Rz 15.00 μm or less using a sand blasting technique.

In addition, the forming of the irregularity physically may be forming the irregularity by spraying a bead having a size of 0.20 mm or less on the processed aluminum alloy at a pressure of 2 to 5 bar.

In addition, the bead may include a ball-type bead and a grit-type bead. A defect on the processed aluminum alloy and a mark caused by a processing tool may be removed by spraying the bead.

In addition, a sparingly soluble salt produced by the phosphorous acid contained in the phosphorous acid mixture and the aluminum alloy having the irregularity formed thereon may be accumulated in a concave portion of the irregularity. A portion corresponding to the concave portion may be prevented or blocked from etching in the aluminum alloy on which the irregularity is formed by the sparingly soluble salt accommodated in the concave portion.

In addition, the immersing of the aluminum alloy may be immersing the aluminum alloy into the phosphorous acid mixture at a room temperature of about 25° C. to 30° C.

In addition, the immersing of the aluminum alloy may be immersing the aluminum alloy into the phosphorous acid mixture for 30 seconds to 210 seconds.

In addition, the phosphorous acid mixture may further contain 0 to 30 g/L of sulfuric acid per 1 L of water.

In addition, the surface of the anodized aluminum alloy may have a hydrophilic property having a water contact angle of 30 to 50°.

In addition, the surface of the anodized aluminum alloy may have a surface roughness value of Ra of 1.00 μm or less and Rz of 8.00 μm or less, and a particle density (spd) of 30,000/mm² to 50,000/mm².

In addition, the aluminum alloy may contain a 6000-series aluminum alloy and a 7000-series aluminum alloy.

Corrosion-resistance, durability, fingerprint-resistance, and hydrophilicity of the aluminum alloy may be secured by chemically treating the aluminum alloy with the phosphorous acid mixture having a designated composition ratio and by anodizing the chemically-treated aluminum alloy.

A surface-treated aluminum alloy according to an embodiment of the disclosure may include an anodizing layer which is produced by forming an irregularity physically on a surface of an aluminum alloy, immersing the aluminum alloy having the irregularity formed thereon into a phosphorous acid mixture, and performing anodizing thereon, and which is exposed to the outside of the anodized aluminum alloy, and an aluminum alloy layer located below the anodizing layer.

In addition, the surface of the anodizing layer may have a water contact angle of 30° to 50° and a surface roughness value of Ra 1.00 μm or less and Rz 8.00 μm or less.

In addition, the surface of the anodizing layer may have a particle density (spd) of 30,000/mm² to 50,000/mm².

In addition, the surface of the anodizing layer may have a gloss value of 15 GU or less.

In addition, the phosphorous acid mixture may contain 15 to 100 ml of the phosphorous acid, 3 to 20 ml of the sodium fluoride, and 1 to 10 ml of the ammonium bifluoride per 1 L of water.

In addition, the irregularity formed physically on the surface of the aluminum alloy may have a surface roughness value of Ra 2.00 μm or less and Rz 15.00 μm or less using a sand blasting technique.

In addition, the irregularity may be formed by spraying a bead having a size of 0.20 mm or less on the aluminum alloy at a pressure of 2 to 5 bar.

In addition, the aluminum alloy having the irregularity formed thereon may be immersed into the phosphorous acid mixture at a room temperature of about 25° C. to 30° C. for 30 seconds to 210 seconds.

In addition, the phosphorous acid mixture may further contain 0 to 30 g/L of sulfuric acid per 1 L of water.

In addition, the anodizing layer may be a surface layer exposed to the outside of the surface-treated aluminum alloy subjected to a sealing operation after the anodizing treatment.

A surface-treated aluminum alloy according to an embodiment of the disclosure may be an aluminum alloy of which a surface is treated using a method including processing the aluminum alloy in a designated shape, forming an irregularity physically on the surface of the aluminum alloy processed in the designated shape, and immersing the aluminum alloy having the irregularity formed thereon into a phosphorous acid mixture containing phosphorous acid, sodium fluoride, and ammonium bifluoride with a designated mixing ratio.

Hereinafter, the disclosure will be described in greater detail with reference to the accompanying drawings.

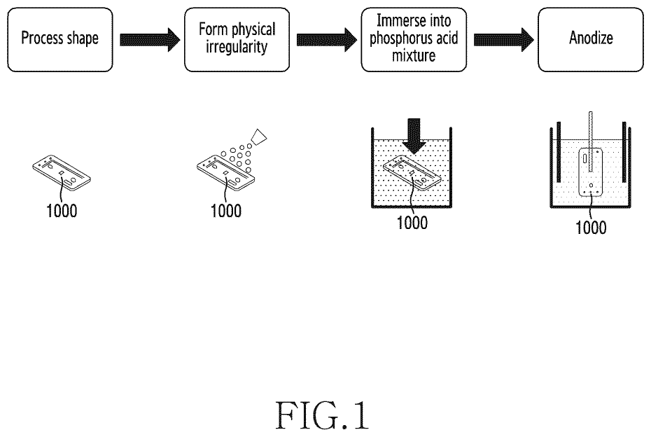

FIG. 1 is a diagram illustrating an example operation of manufacturing an anodized aluminum alloy according to various embodiments.

Referring to FIG. 1, after an aluminum alloy 1000 is processed to have a designated shape, a physical irregularity having a designated surface roughness value may be formed on a surface of the processed aluminum alloy 1000. The physical irregularity may be an irregularity formed by a physical processing method. The aluminum alloy 1000 having the physical irregularity formed thereon may be immersed into a phosphorous acid mixture having a designated mixing ratio, and an anodizing treatment may be performed on the aluminum alloy 1000 immersed into the phosphorous acid mixture.

According to an embodiment, since the physical irregularity is formed on the surface of the aluminum alloy 1000 and is chemically treated with the phosphorous acid mixture prior to the anodizing, the anodized aluminum alloy 1000 may have a hydrophilic surface with fine and high particle density. The aluminum alloy 1000 having the hydrophilic surface may have fingerprint-resistant and contamination-resistant properties.

The aluminum alloy 1000 may include, for example, a 6000-series aluminum alloy and a 7000-series aluminum alloy. The 6000-series aluminum alloy may be manufactured by adding magnesium and silicon to aluminum, and copper may be further added. The 6000-series aluminum alloy may be selected from, for example, Al 6063, Al 6061, Al 6005A, Al 6N01, Al 6351, Al 6151, Al 6262, and Al 6101. The 7000-series aluminum alloy may be manufactured by adding zinc and magnesium to aluminum, and copper may be further added. The 7000-series aluminum alloy may be selected from, for example, Al 7003, Al 7010, Al 7050, Al 7072, Al 7075, Al 7175, Al 7475, Al 7178, Al 7079, and Al 7N01.

The anodized aluminum alloy 1000 may be used as a housing of an electronic device. The electronic device may include, for example, a portable communication device (e.g., a smartphone), a computer device, a portable multimedia device, a portable medical device, a camera, a wearable device, or a home appliance device. The electronic device according to an embodiment of the disclosure is not limited to the aforementioned devices.

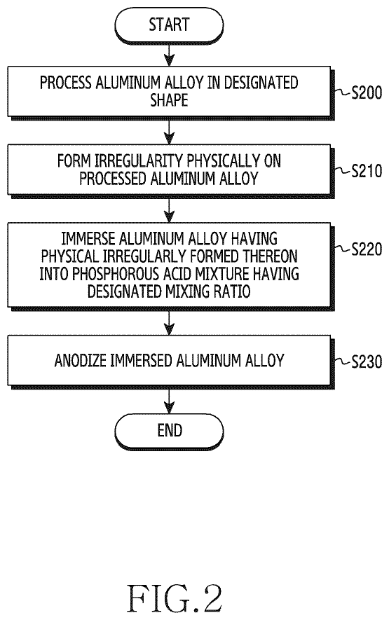

FIG. 2 is a flowchart illustrating an example method of manufacturing an anodized aluminum alloy according to various embodiments.

An operation S200 may include a processing operation for processing the aluminum alloy 1000 in a designated shape. The aluminum alloy 1000 may be processed in the designated shape by at least one of press processing, casting processing, polishing processing, cutting processing, extrusion processing, forging processing, and Computerized Numerical Control (CNC) processing. The aluminum alloy 1000 may be processed in a shape to be used as a housing of an electronic device.

An operation S210 may include an operation for forming a physical irregularity on the processed aluminum alloy 1000. The physical irregularity may be formed on the aluminum alloy 1000 through sand blasting using a bead of a specific size. For example, since the bead produced based on a material such as alumina oxide, zirconia oxide, titanium oxide, silicon oxide, and/or boron carbide is sprayed on the aluminum alloy 1000, the physical irregularity may be formed on the aluminum alloy 1000. The bead for sand blasting may have, but is not limited to, for example, a ball-type shape and/or a grit-type shape.

For example, since a bead of 0.20 mm or less is sprayed toward the surface of the aluminum alloy 1000 at a pressure of 2 to 5 bar, scratches and defects on the surface of the aluminum alloy 1000 may be removed, and a fine physical irregularity having a surface roughness value of Ra 2.00 μm or less and Rz 15.00 μm or less may be formed on the aluminum alloy 1000. A shape and size of the bead may be selectively used by considering a texture and water contact angle of the surface of the aluminum alloy 1000.

Since the aluminum alloy 1000, on which the fine physical irregularity having a surface roughness value of Ra 2.00 μm or less and Rz 15.00 μm or less is formed, is immersed into a phosphorous acid mixture and then is anodized, hydrophilicity of the surface of the anodized aluminum alloy 1000 may be secured, thereby implementing the aluminum alloy 1000 having fingerprint-resistant and contamination-resistant properties. On the other hand, when the aluminum alloy 1000, on which the physical irregularity having the surface roughness value of Ra 2.00 μm or more and Rz 15.00 μm or more is formed, is immersed into the phosphorous acid mixture and is then anodized, the hydrophilicity of the surface of the anodized aluminum alloy 1000 becomes insufficient due to a lotus leaf effect.

Although it is described above that the physical irregularity is formed on the aluminum alloy 1000 through the sand blasting using the bead of the specific size, the physical irregularity may be formed on the aluminum alloy 1000 using a tool, or the physical irregularity may be formed on the aluminum alloy 1000 through polishing.

An operation S220 may include an operation of immersing the aluminum alloy 1000 having the physical irregularity formed thereon into the phosphorous acid mixture having a designated mixing ratio. The aluminum alloy 1000 on which the fine physical irregularity having a surface roughness value of Ra of 2.00 μm or less and Rz of 15.00 μm or less is formed may be immersed into the phosphorous acid mixture containing phosphorous acid, sodium fluoride, and ammonium bifluoride at a designated temperature for a designated treatment time.

The sand blasting operation alone has a limitation in implementing the hydrophilic surface on the aluminum alloy 1000. Corrosion-resistance, durability, and hydrophilicity of the aluminum alloy 1000 may be secured by chemically treating the aluminum alloy 1000 with the phosphorous acid mixture having a designated composition ratio and by anodizing the chemically-treated aluminum alloy 1000.

For example, after immersing the aluminum alloy 1000 into the phosphorous acid mixture containing 10 to 100 ml of phosphorous acid, 3 to 20 ml of sodium fluoride, and 1 to 10 ml of ammonium bifluoride per 1 L of water at a room temperature of about 25° C. to 30° C. for 30 seconds to 210 seconds, anodizing to be described later is carried out so that the aluminum alloy 1000 may have a hydrophilic surface having a water contact angle of 30 to 50°.

Optionally, for pH adjustment and chemical reaction of the phosphorous acid mixture, sulfuric acid may be added to the phosphorous acid mixture. For example, 0 to 30 g/L of sulfuric acid per 1 L of water may be added to the phosphorous acid mixture to which 10 to 100 ml of phosphorous acid, 3 to 20 ml of sodium fluoride, and 1 to 10 ml of ammonium bifluoride are mixed per 1 L of water.

According to an embodiment, in order to increase the hydrophilicity of the surface of the aluminum alloy 1000, the aluminum alloy 1000 having the physical irregularity formed thereon may be immersed into a phosphorous acid mixture within a specific concentration range. For example, the aluminum alloy 1000 may be immersed into a phosphorous acid mixture containing 10 to 20 ml of phosphorous acid, 3 to 5 ml of sodium fluoride, and 1 to 1.5 ml of ammonium bifluoride per 1 L of water, or the aluminum alloy 1000 may be immersed into a phosphorous acid mixture containing 20 to 40 ml of phosphorous acid, 5 to 7 ml of sodium fluoride, and 1.5 to 2.5 ml of ammonium bifluoride per 1 L of water, or the aluminum alloy 1000 may be immersed into a phosphorous acid mixture containing 40 to 50 ml of phosphorous acid, 7 to 10 ml of sodium fluoride, and 2.5 to 3.5 ml of ammonium bifluoride per 1 L of water. However, the disclosure is not limited thereto.

Since the aluminum alloy 1000 having the physical irregularity formed thereon is immersed into the phosphorous acid mixture, phosphorous acid in the phosphorous acid mixture may react with aluminum in the aluminum alloy 1000 to produce a sparingly soluble salt. The produced sparingly soluble salt may be located at a concave portion of the physical irregularity to prevent or block the aluminum alloy 1000 from being etched by the phosphorous acid mixture. Accordingly, the etching reaction may occur more actively in a peak portion than in the concave portion of the physical irregularity, and the surface of the aluminum alloy 1000 may be refined while the physical irregularity of the aluminum alloy 1000 is maintained.

An operation S230 may include an operation of anodizing the immersed aluminum alloy. The anodizing operation is an operation of forming a porous oxide film, and may use sulfuric acid, hydroxide, phosphoric acid, and/or chromic acid as an electrolyte used for the anodizing operation. A voltage to be applied, temperature, and/or immersion time of the anodizing operation may be adjusted depending on a purpose of the oxide film formed on the aluminum alloy 1000. For example, the anodizing operation may be applied to an electrolyte containing 150 g/L to 300 g/L of sulfuric acid, within a range of conditions in which a treatment temperature is 0 to 30° C., a voltage is 5 to 40V, an immersion time is 10 minutes to 3 hours, and a temperature of the electrolyte is 5 to 30° C.

Through the anodizing operation, an aluminum oxide film may be formed on the surface of the aluminum alloy 1000. The oxide film increases wear-resistance and corrosion-resistance of the aluminum alloy 1000. The oxide film, which is porous, facilitates coloring of the aluminum alloy 1000, and may maintain a gloss of the aluminum alloy 1000.

Although it is described in FIG. 2 that the aluminum alloy 1000 is anodized through the operations S200, S210, S220, and S230, the disclosure is not limited thereto. A degreasing operation and a cleaning operation may be additionally performed between the operations S200, S210, S220, and S230.

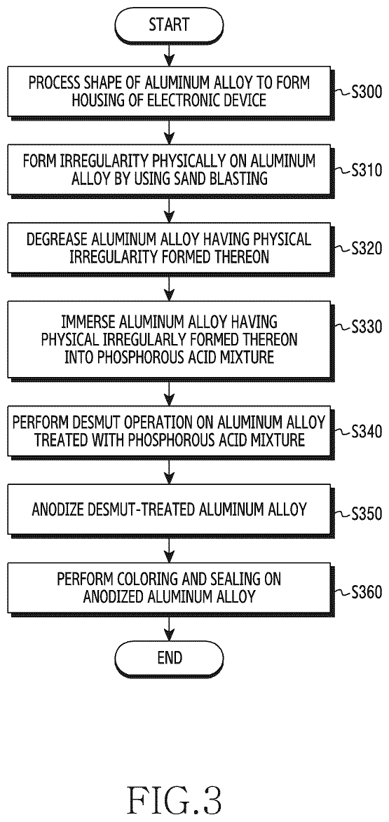

FIG. 3 is a flowchart illustrating an example method of manufacturing an anodized aluminum alloy according to various embodiments.

Operations S300, S310, S330, and S350 may correspond to the operations S200, S210, S220, and S230 of FIG. 2.

The operation S300 may include a processing operation for processing the aluminum alloy 1000 in a designated shape. The aluminum alloy 1000 may be processed in the designated shape by at least one of press processing, casting processing, polishing processing, cutting processing, extrusion processing, forging processing, and CNC processing. The aluminum alloy 1000 may be processed in a shape to be used as a housing of an electronic device.

The operation S310 may include an operation for forming a physical irregularity on the processed aluminum alloy. The physical irregularity may be formed on the aluminum alloy 1000 through sand blasting using a bead of a specific size. For example, since the bead produced based on a material such as alumina oxide, zirconia oxide, titanium oxide, silicon oxide, and/or boron carbide is sprayed on the aluminum alloy 1000, the physical irregularity may be formed on the aluminum alloy 1000. The bead for sand blasting may have, but is not limited to, for example, a ball-type shape and/or a grit-type shape.

For example, since a bead of 0.20 mm or less is sprayed toward the surface of the aluminum alloy 1000 at a pressure of 2 to 5 bar, scratches and defects on the surface of the aluminum alloy 1000 may be removed, and a fine physical irregularity having a surface roughness value of Ra 2.00 μm or less and Rz 15.00 μm or less may be formed on the aluminum alloy 1000. A shape and size of the bead may be selectively used by considering a texture and water contact angle of the surface of the aluminum alloy 1000.

Since the aluminum alloy 1000, on which the fine physical irregularity having a surface roughness value of Ra 2.00 μm or less and Rz 15.00 μm or less is formed, is immersed into a phosphorous acid mixture and then is anodized, hydrophilicity of the surface of the anodized aluminum alloy 1000 may be secured, thereby implementing the aluminum alloy 1000 having fingerprint-resistant and contamination-resistant properties. On the other hand, when the aluminum alloy 1000, on which the physical irregularity having the surface roughness value of Ra 2.00 μm or more and Rz 15.00 μm or more is formed, is immersed into the phosphorous acid mixture and is then anodized, the hydrophilicity of the surface of the anodized aluminum alloy 1000 becomes insufficient due to a lotus leaf effect.

Although it is described above that the physical irregularity is formed on the aluminum alloy 1000 through the sand blasting using the bead of the specific size, the physical irregularity may be formed on the aluminum alloy 1000 using a tool, or the physical irregularity may be formed on the aluminum alloy 1000 through polishing.

An operation S320 may include an operation of degreasing the aluminum alloy 1000 having the physical irregularity formed thereon. On the surface of the aluminum alloy 1000 having the physical irregularity formed thereon, foreign substances and oil produced in the processing operation may exist, and the foreign substances and oil on the surface of the aluminum alloy 1000 having the physical irregularity formed thereon may be removed by a degreasing solution. For example, the degreasing operation may include, but is not limited to, an organic solvent method which uses trichloroethylene and/or benzene as the degreasing solution, a surfactant method which uses a soap, a neutral detergent, and a synthetic agent as the degreasing solution, a sulfuric acid method which uses diluted sulfuric acid, an electrolytic degreasing method which uses an electrolyte, an emulsification degreasing method which uses a mixture of kerosene as a surfactant and water, and/or a phosphate method which uses sodium carbonate, phosphates, and a surfactant.

In the degreasing operation, the aluminum alloy 1000 may be immersed into the degreasing solution in the degreasing operation. After the degreasing operation, the aluminum alloy 1000 may be cleaned through a cleaning operation.

The operation S330 may include an operation of immersing the degreased aluminum alloy aluminum alloy 1000 having the physical irregularity formed thereon into a phosphorous acid mixture having a designated mixing ratio. After degreasing the aluminum alloy 1000 on which the fine physical irregularity having a surface roughness value of Ra of 2.00 μm or less and Rz of 15.00 μm or less is formed, the degreased aluminum alloy 1000 may be immersed into the phosphorous acid mixture containing phosphorous acid, sodium fluoride, and ammonium bifluoride at a designated temperature for a designated treatment time.

The sand blasting operation alone has a limitation in implementing the hydrophilic surface on the aluminum alloy 1000. Corrosion-resistance, durability, and hydrophilicity of the aluminum alloy 1000 may be secured by chemically treating the aluminum alloy 1000 with the phosphorous acid mixture having a designated composition ratio and by anodizing the chemically-treated aluminum alloy 1000.

For example, after immersing the aluminum alloy 1000 into phosphorous acid mixture containing 10 to 100 ml of phosphorous acid, 3 to 20 ml of sodium fluoride, and 1 to 10 ml of ammonium bifluoride per 1 L of water at a room temperature of about 25° C. to 30° C. for 30 seconds to 210 seconds, anodizing to be described later is carried out so that the aluminum alloy 1000 may have a hydrophilic surface having a water contact angle of 30 to 50°.

Optionally, for pH adjustment and chemical reaction of the phosphorous acid mixture, sulfuric acid may be added to the phosphorous acid mixture. For example, 0 to 30 g/L of sulfuric acid per 1 L of water may be added to the phosphorous acid mixture to which 10 to 100 ml of phosphorous acid, 3 to 20 ml of sodium fluoride, and 1 to 10 ml of ammonium bifluoride are mixed per 1 L of water.

According to an embodiment, in order to increase the hydrophilicity of the surface of the aluminum alloy 1000, the degreased aluminum alloy 1000 having the physical irregularity formed thereon may be immersed into a phosphorous acid mixture within a specific concentration range. For example, the aluminum alloy 1000 may be immersed into a phosphorous acid mixture containing 10 to 20 ml of phosphorous acid, 3 to 5 ml of sodium fluoride, and 1 to 1.5 ml of ammonium bifluoride per 1 L of water, or the aluminum alloy 1000 may be immersed into a phosphorous acid mixture containing 20 to 40 ml of phosphorous acid, 5 to 7 ml of sodium fluoride, and 1.5 to 2.5 ml of ammonium bifluoride per 1 L of water, or the aluminum alloy 1000 may be immersed into a phosphorous acid mixture containing 40 to 50 ml of phosphorous acid, 7 to 10 ml of sodium fluoride, and 2.5 to 3.5 ml of ammonium bifluoride per 1 L of water. However, the disclosure is not limited thereto.

Since the degreased aluminum alloy 1000 having the physical irregularity formed thereon is immersed into the phosphorous acid mixture, phosphorous acid in the phosphorous acid mixture may react with aluminum in the aluminum alloy 1000 to produce a sparingly soluble salt. The produced sparingly soluble salt may be located at a concave portion of the physical irregularity to prevent or block the aluminum alloy 1000 from being etched by the phosphorous acid mixture. Accordingly, the etching reaction may occur more actively in a peak portion than in the concave portion of the physical irregularity, and the surface of the aluminum alloy 1000 may be refined while the physical irregularity of the aluminum alloy 1000 is maintained.

An operation S340 may include a desmut operation for removing a smut on the aluminum alloy 1000 treated with a phosphorous acid mixture. Aluminum is an amphoteric metal which may react with both acid and alkali to cause an oxidation-reduction reaction. For example, when an oxidation reaction occurs, an oxide film is removed on a surface of aluminum and the aluminum is croded, and at the same time, other metal ions dissolved in an acid or alkaline cleaning solution may be reduced to the (−) charged aluminum surface. For example, copper and magnesium may be reduced to form a smut on the aluminum surface. In order not to have a negative effect on a subsequent operation, a smut on the aluminum alloy 1000 treated with the phosphorous acid mixture may be removed through the desmut operation.

The operation S350 may include an operation of anodizing the desmut-treated aluminum alloy. The anodizing operation is an operation of forming a porous oxide film, and may use sulfuric acid, hydroxide, phosphoric acid, and/or chromic acid as an electrolyte used for the anodizing operation. A voltage to be applied, temperature, and/or immersion time of the anodizing operation may be adjusted depending on a purpose of the oxide film formed on the aluminum alloy 1000. For example, the anodizing operation may be applied to an electrolyte containing 150 g/L to 300 g/L of sulfuric acid, within a range of conditions in which a treatment temperature is 0 to 30° C., a voltage is 5 to 40V, an immersion time is 10 minutes to 3 hours, and a temperature of the electrolyte is 5 to 30° C.

An operation 360 may include an operation of coloring and sealing the anodized aluminum alloy 1000.

The coloring operation is an operation of coloring the aluminum alloy 1000 in a desired color, and a known coloring method may be used. For example, the coloring operation may be performed by immersing the aluminum alloy 1000 into a coloring solution containing a dye for a specific time. A treatment time and temperature of the coloring dye may be properly adjusted in consideration of a type and concentration of the dye in use. A dye solution may remain on the surface of the aluminum alloy 1000 subjected to the coloring operation, and a cleaning operation may be performed to remove the remaining dye solution.

The sealing operation may include an operation of filling a fine pore formed on an oxide film on the surface of the aluminum alloy 1000. For example, the sealing operation may include an operation of immersing the aluminum alloy 1000 into high-temperature water, an operation of sealing the fine pore formed on the oxide film using high-temperature steam, and an operation of sealing the fine pore formed on the oxide film using a metal salt or an organic substance. However, the disclosure is not limited thereto, and the sealing operation may be performed using various compositions. After the sealing operation, an operation of drying the aluminum alloy 1000 may be added.

Since the anodizing operation is performed after immersing the aluminum alloy 1000 having a fine irregularity formed thereon through the sand blasting operation into the phosphorous acid mixture, a hydrophilic surface may be realized on the aluminum alloy 1000, and corrosion-resistance and durability of the aluminum alloy 1000 may be secured.

Table 1 is a table for explaining a mixing ratio of the phosphorous acid mixture according to an embodiment of the disclosure.

TABLE 1

| | name of used | | | |
|---|---|---|---|---|
| | chemical | component | concentration | |
| phosphorous acid | water | RO | | |
| mixture | phosphorous acid | phosphorous acid | 10~100 | ml/l |
| | sodium fluoride | sodium fluoride | 3~20 | ml/l |
| | ammonium | ammonium | 1~10 | ml/l |
| | bifluoride | bifluoride | | |
| | sulfuric acid (98%) | H2SO4 (98%) | 0~30 | g/l |

Referring to Table 1, the phosphorous acid mixture may contain water, phosphorous acid, sodium fluoride, and ammonium bifluoride. For example, the phosphorous acid mixture may include 10 to 100 ml of the phosphorous acid, 3 to 20 ml of the sodium fluoride, and 1 to 10 ml of the ammonium bifluoride per 1 L of water.

Optionally, for pH adjustment and chemical reaction of the phosphorous acid mixture, the phosphorous acid mixture may further contain sulfuric acid (98%). For example, when the sulfuric acid is added to the phosphorous acid mixture, 0 to 30 g/L of the sulfuric acid per 1 L of water may be added to the phosphorous acid mixture.

Table 2 is a table for explaining a treatment condition of specific operations for treating a surface of an aluminum alloy according to an embodiment of the disclosure.

TABLE 2

| | input material | | | | | |
|---|---|---|---|---|---|---|
| name of | name of used | | | | | treatment |
| operation | chemical | component | concentration | | temperature | time |
| degreasing | water | RO | | | 50° C. | 2 min |
| (acidic) | nitric Acid | HNO3 68% | 70 | g/L | | |
| | (68%) | | | | | |
| | degreasing | surfactant | 50 | g/L | | |
| | agent | | | | | |
| immersing | water | RO | | | room | 30~210 |
| into | phosphorous | phosphorous | 10~100 | ml/l | temperature | sec |
| phosphorous | acid | acid | | | | |
| acid mixture | sodium | sodium | 3~20 | ml/l | | |
| | fluoride | fluoride | | | | |
| | ammonium | ammonium | 1~10 | ml/l | | |
| | bifluoride | bifluoride | | | | |
| | sulfuric acid | H2SO4 98% | 0~30 | g/l | | |
| | (98%) | | | | | |
| desmut | water | RO | | | room | 2 min |
| | nitric Acid | HNO3 68% | 550 | g/l | temperature | |
| | (68%) | | | | | |
| anodizing | water | RO | | | 10° C. | 11 V |
| | sulfuric acid | H2SO4 98% | 250 | g/l | | 60 min |
| | (98%) | | | | | |
| | aluminum | aluminum | 5 | g/l | | |
| | sulfate | sulfate | | | | |
| coloring | water | RO | | | 45° C. | varies by |
| | dye | varies by | | | | condition |
| | | condition | | | | |
| sealing | water | RO | | | 90° C. | |
| | sealing | nickel | 45 | g/l | | 60 min |
| | solution | acetate | | | | |
| drying | | | | | 90° C. | 20 min |

The operations described in Table 2 may be applied to the operations of FIG. 2 and FIG. 3.

Referring to Table 2, for the degreasing operation, a degreasing solution containing a degreasing agent including a surfactant, water, and nitric acid (68%) may be used. For example, the degreasing solution may contain about 70 g/L of nitric acid (68%) and about 50 g/L of the degreasing agent per 1 L of water. The aluminum alloy 1000 may be immersed into the degreasing agent at a treatment temperature of about 50° C. for a treatment time of about 2 minutes.

In the operation of immersing the aluminum alloy 1000 into the phosphorous acid mixture, the aluminum alloy 1000 may be immersed into the phosphorous acid mixture of Table 1 for a treatment time of 20 to 210 seconds at a room temperature of about 25 to 30° C.

In the desmut operation, a desmut solution containing water and nitric acid (68%) may be used. The desmut solution may contain about 550 g/L of nitric acid (68%) per 1 L of water. The aluminum alloy 1000 may be immersed into the desmut solution at a room temperature of about 25 to 30° C. for a treatment time of about 2 minutes.

In the anodizing operation, an anodizing solution containing water, sulfuric acid (98%), and aluminum sulfate may be used. The anodizing solution used in the anodizing operation may contain about 250 g/L of sulfuric acid (98%) and about 5 g/L of aluminum sulfate per 1 L of water. The aluminum alloy 1000 may be immersed into the anodizing solution for about 60 minutes at a temperature of about 10° C. in a situation where a voltage of 11V is applied.

In the coloring operation, the aluminum alloy 1000 may be immersed into a coloring solution containing water and a dye at a temperature of about 45° C.

In the sealing operation, a sealing solution containing water and a sealant may be used. The sealing solution may contain about 45 g/L of the sealant per 1 L of water. For example, the sealant may contain nickel acetate. The aluminum alloy 1000 may be immersed at a temperature of about 90° C. for about 60 minutes.

The drying operation may be performed at a temperature of about 90° C. for about 20 minutes.

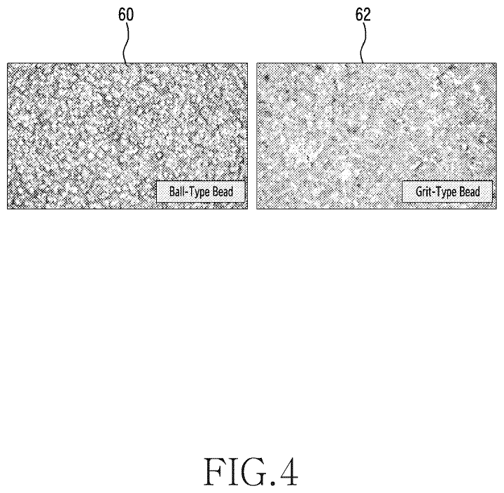

FIG. 4 is a diagram illustrating example physical irregularity formed on an aluminum alloy through sand blasting according to various embodiments.

FIG. 4 may illustrate results 60 and 62 based on an operation of forming the physical irregularity of FIG. 2 and FIG. 3.

Referring to the result 60 based on the operation of forming the physical irregularity, since a bead having a ball-type shape of 0.20 mm or less is sprayed toward the surface of the aluminum alloy 1000 at a pressure of 2 to 5 bar, scratches and defects on the surface of the aluminum alloy 1000 may be removed, and a fine physical irregularity having a surface roughness value of Ra 2.00 μm or less and Rz 15.00 μm or less may be formed on the aluminum alloy 1000.

In addition, referring to the result 62 based on the operation of forming the physical irregularity, since a bead having a grit-type shape of 0.20 mm or less is sprayed toward the surface of the aluminum alloy 1000 at a pressure of 2 to 5 bar, scratches and defects on the surface of the aluminum alloy 1000 may be removed, and a fine physical irregularity having a surface roughness value of Ra 2.00 μm or less and Rz 15.00 μm or less may be formed on the aluminum alloy 1000.

Since the fine physical irregularity is preferentially formed on the surface of the aluminum alloy 1000, the surface of the anodized aluminum alloy 1000 may have hydrophilicity and a uniform appearance.

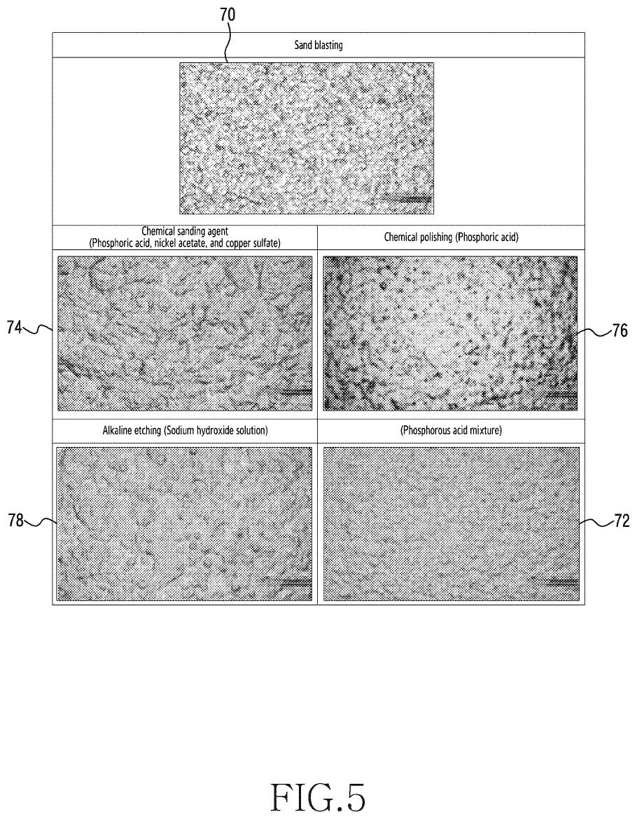

FIG. 5 is a diagram comparing a result of treating an aluminum alloy having a physical irregularity formed thereon with a phosphorous acid mixture and a result of treating it with other chemical substances according to various embodiments.

In FIG. 5, a result 72 of treating an aluminum alloy 70 on which a physical irregularity is formed through the operation for the physical irregularity of FIG. 2 and FIG. 3 with the phosphorous acid mixture of FIG. 2 and FIG. 3 is illustrated as well as results 74, 76, and 78 of treating the aluminum alloy 70 on which the physical irregularity is formed through the operation for the physical irregularity of FIG. 2 and FIG. 3 with other chemical substances.

The reference numeral 70 denotes the surface of the aluminum alloy 1000 on which the physical irregularity is formed through the operation for the physical irregularity of FIG. 2 and FIG. 3.

The reference numeral 72 denotes the surface of the aluminum alloy 1000 when the aluminum alloy 1000 having the physical irregularity formed thereon is treated with the phosphorous acid mixture and is then anodized. The reference numeral 74 denotes the surface of the aluminum alloy 1000 when the aluminum alloy 1000 having the physical irregularity formed thereon is treated with a chemical sanding agent containing phosphoric acid, nickel acetate, and copper sulfate and is then anodized. The reference numeral 76 denotes the surface of the aluminum alloy 1000 when the aluminum alloy 1000 having the physical irregularity formed thereon is chemically polished with a phosphoric acid solution and then is anodized. The reference numeral 78 denotes the surface of the aluminum alloy 1000 when the aluminum alloy 1000 having the physical irregularity formed thereon is alkaline etched with a sodium hydroxide solution and is then anodized.

Referring to FIG. 5, the surface 72 of the aluminum alloy 1000 treated with the phosphorous acid mixture may maintain a finer and more uniform irregularity than the surfaces 74, 76, and 78 of the aluminum alloy 1000 treated with other chemical substances, and hydrophilicity, fingerprint-resistance, and contamination-resistance of the aluminum alloy 1000 may be improved.

In case of chemical polishing, a phosphoric acid solution is mainly used, and a water contact angle is about 70° after an anodized film is formed. In case of chemical sanding or alkaline etching, due to etching of the surface of the aluminum alloy 1000, a fine hole such as a pin hole is formed on the aluminum alloy 1000, and due to a resultant lotus leaf effect, the surface of the aluminum alloy 1000 has high hydrophobicity with a water contact angle of about 100°.

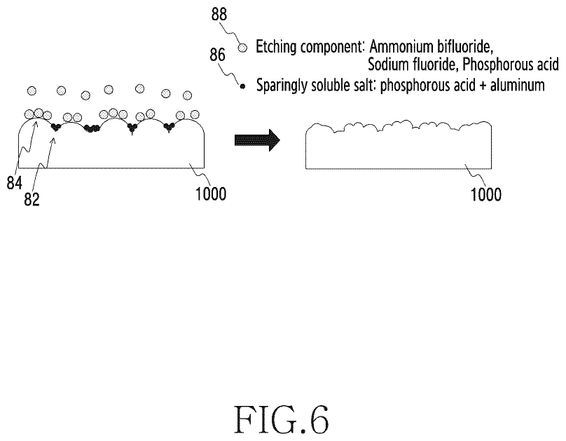

FIG. 6 is a diagram illustrating an example operation in which a physical irregularity formed on an aluminum alloy is etched by a phosphorous acid mixture according to various embodiments.

In FIG. 6, an operation in which a surface of an aluminum alloy 1000 on which a physical irregularity is formed through the operation for the physical irregularity of FIG. 2 and FIG. 3 is treated by the phosphorous acid mixture of FIG. 2 and FIG. 3 is illustrated.

Referring to FIG. 6, the physical irregularity of the aluminum alloy 1000 having the physical irregularity formed thereon may include a concave portion 82 and a peak portion 84. Since the aluminum alloy 1000 having the physical irregularity formed thereon is immersed into the phosphorous acid mixture, phosphorous acid in the phosphorous acid mixture may react with aluminum in the aluminum alloy 1000 to produce a sparingly soluble salt 86.

The sparingly soluble salt 86 may be accumulated on the concave portion 82 of the physical irregularity. Due to the sparingly soluble salt 86 accumulated on the concave portion 82, the aluminum alloy 1000 of the concave portion 82 may be prevented or blocked from being etched by an etching component 88 of the phosphorous acid mixture. The etching component 88 of the phosphorous acid mixture may etch the aluminum alloy 1000 more actively at the peak portion 84 than in the concave portion 82 of the physical irregularity. Accordingly, the surface of the aluminum alloy 1000 may be refined while maintaining the physical irregularity on the surface of the aluminum alloy 1000.

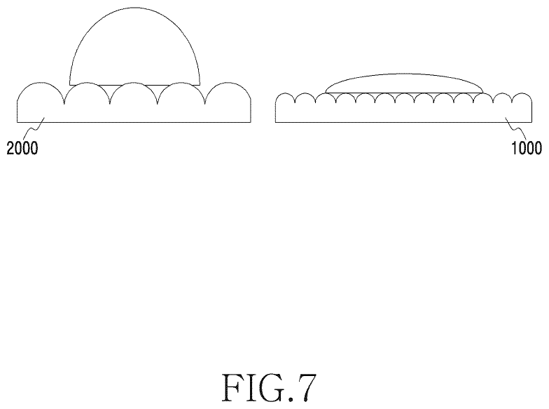

FIG. 7 is a diagram illustrating example hydrophilicity of an aluminum alloy having a fine irregularity according to various embodiments.

Referring to FIG. 7, a water contact angle on a surface of an aluminum alloy 1000 having a fine irregularity formed thereon is smaller than a water contact angle on a surface of an aluminum alloy 2000 having a large irregularity formed thereon. Accordingly, the surface of the aluminum alloy 1000 having the fine irregularity formed thereon is more hydrophilic than the surface of the aluminum alloy 2000 having the large irregularity formed thereon.

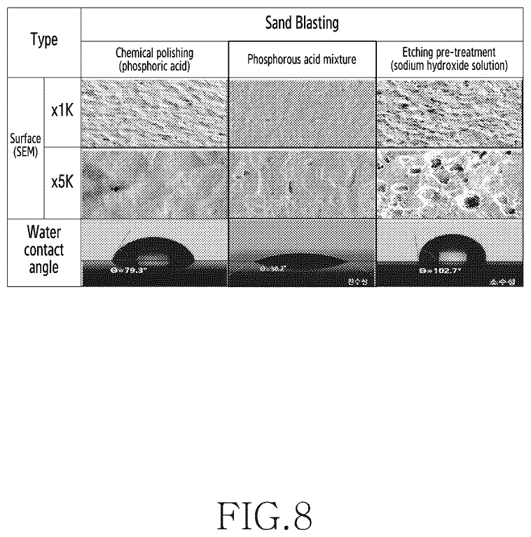

FIG. 8 is a diagram illustrating a water contact angle and a surface of an aluminum alloy of which the surface is treated according to various embodiments.

In FIG. 8, a result obtained by treating an aluminum alloy on which a physical irregularity is formed through the operation for the physical irregularity of FIG. 2 and FIG. 3 with the phosphorous acid mixture of FIG. 2 and FIG. 3 is illustrated as well as results obtained by treating an aluminum alloy on which a physical irregularity is formed through the operation for the physical irregularity of FIG. 2 and FIG. 3 with other chemical substances.

Referring to FIG. 8, for example, when an aluminum alloy 1000 having a physical irregularity formed thereon is treated with a phosphorous acid mixture and then is anodized, a surface of the aluminum alloy 1000 has a water contact angle of 30.2°. For example, when the aluminum alloy 1000 having the physical irregularity formed thereon is chemically polished with a phosphoric acid solution and then is anodized, the surface of the aluminum alloy 1000 has a water contact angle of 79.3°. For example, when the aluminum alloy 1000 having the physical irregularity formed thereon is alkaline etched with a sodium hydroxide solution and then is anodized, the surface of the aluminum alloy 1000 has a water contact angle of 102.7°.

When the aluminum alloy 1000 having the physical irregularity formed thereon is treated with the phosphorous acid mixture and then is anodized, the surface of the aluminum alloy 1000 may include finer and more uniform irregularities than those treated with other chemical substances. When it is treated with the phosphorous acid mixture and then is anodized, a lotus leaf effect caused by a fine hole such as a pin hole may be avoided in the surface of the aluminum alloy 1000.

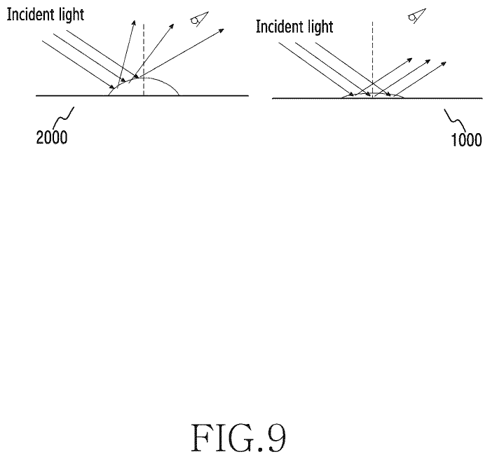

FIG. 9 is a diagram illustrating fingerprint-resistance depending on a water contact angle of an aluminum alloy according to various embodiments.

Referring to FIG. 9, a water contact angle on a surface of an aluminum alloy 1000 of which the surface is treated according to an embodiment of the disclosure is smaller than a water contact angle on a surface of an aluminum alloy 2000 of which the surface is treated by including another chemical treatment.

Since the surface of the aluminum alloy 1000 of which the surface is treated according to an embodiment of the disclosure has the small water contact angle, the surface has hydrophilicity, and contamination of the surface may be avoided. When the surface has the hydrophilicity, light on the surface is reflected close to direct reflection, thereby exhibiting an effect of decreasing visibility of a fingerprint. The fingerprint is recognized by a person through light reflection on a material, and the fingerprint is visible to the person in an environment where direct reflection light and indirect reflection light coexist.

The surface of the aluminum alloy 2000 of which the surface is treated by including another chemical treatment has a high water contact angle and has hydrophobicity. When the surface has the hydrophobicity, light is reflected in a diffuse reflection manner on the surface, thereby increasing the visibility of the fingerprint. A contaminant forms on the hydrophobic surface in a shape of water droplets, and the hydrophobic surface is not good for cleaning the contaminant.

When hydrophilicity is granted to a material surface, such as the surface-treated aluminum alloy 1000 according to an embodiment of the disclosure, water spreads widely on the hydrophilic surface, and the hydrophilic surface has an anti-contamination function and exhibits a self-cleaning effect.

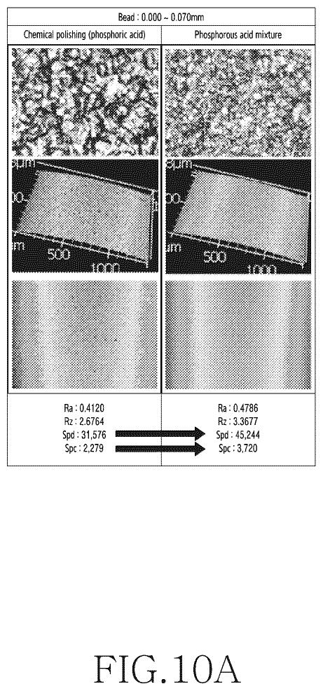

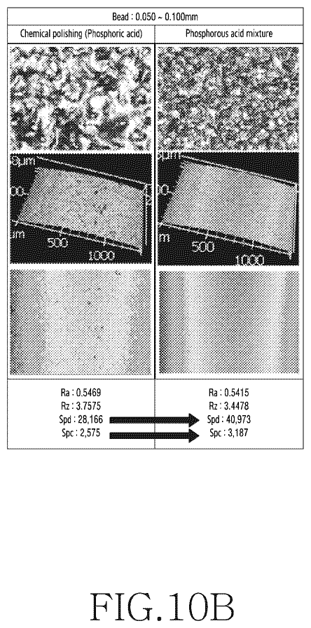

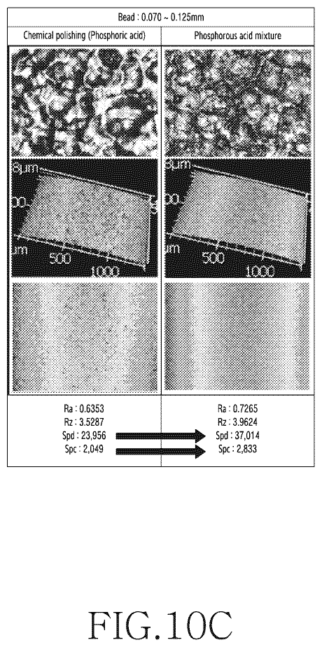

FIG. 10A is a diagram comparing a surface of an aluminum alloy on which a physical irregularity is formed by sand blasting using a bead of 0.070 mm or less when the aluminum alloy is immersed into a phosphorous acid mixture and when the aluminum alloy is immersed into a phosphoric acid solution according to various embodiments.

Referring to FIG. 10A, when the aluminum alloy 1000 on which the physical irregularity is formed by sand blasting using the bead of 0.070 mm or less is immersed into the phosphoric acid solution, the aluminum alloy 1000 is measured such that Ra is 0.4120, Rz is 2.6764, Spd (peak density, the number of peaks within a reference area of 1 mm²) is 31576, and Spc (arithmetic peak mean curvature) is 2279.

When the aluminum alloy 1000 on which the physical irregularity is formed by sand blasting using the bead of 0.070 m or less is immersed into the phosphorous acid mixture, the aluminum alloy 1000 is measured such that Ra is 0.4786, Rz is 3.3677, Spd is 45244, and Spc is 3720.

Spd denotes the number of peaks of irregularities within a reference area of 1 mm² on a material surface. The denser the irregularities on the surface and the higher the particle density on the surface, the higher the value Spd of the surface.

Spc denotes an average curvature value of peaks of irregularities within a reference area of 1 mm² on a material surface. The more round the peaks, the smaller the value Spc of the surface. The sharper the peaks, the larger the value Spc of the surface. The larger the value Spc of the surface, the more refined the surface particles.

FIG. 10B is a diagram comparing a surface of an aluminum alloy on which a physical irregularity is formed by sand blasting using a bead of 0.050 to 0.100 mm when the aluminum alloy is immersed into a phosphorous acid mixture and when the aluminum alloy is immersed into a phosphoric acid solution according to various embodiments.

Referring to FIG. 10B, when the aluminum alloy 1000 on which the physical irregularity is formed by sand blasting using the bead of 0.050 to 0.100 mm is immersed into the phosphoric acid solution, the aluminum alloy 1000 is measured such that Ra is 0.5469, Rz is 3.7575, Spd is 28166, and Spc is 2575.

When the aluminum alloy 1000 on which the physical irregularity is formed by sand blasting using the bead of 0.050 to 0.100 mm is immersed into the phosphorous acid mixture, the aluminum alloy 1000 is measured such that Ra is 0.5415, Rz is 3.4478, Spd is 40973, and Spc is 3187.

FIG. 10C is a diagram comparing a surface of an aluminum alloy on which a physical irregularity is formed by sand blasting using a bead of 0.070 mm to 0.125 mm when the aluminum alloy is immersed into a phosphorous acid mixture and when the aluminum alloy is immersed into a phosphoric acid solution according to various embodiments.

Referring to FIG. 10C, when the aluminum alloy 1000 on which the physical irregularity is formed by sand blasting using the bead of 0.070 mm to 0.125 mm is immersed into the phosphoric acid solution, the aluminum alloy 1000 is measured such that Ra is 0.6353, Rz is 3.5287, Spd is 23956, and Spc is 2049.

When the aluminum alloy 1000 on which the physical irregularity is formed by sand blasting using the bead of 0.070 mm to 0.125 mm is immersed into the phosphorous acid mixture, the aluminum alloy 1000 is measured such that Ra is 0.7265, Rz is 3.9624, Spd is 37014, and Spc is 2833.

Referring to FIGS. 10A, 10B and 10C, it is identified that the value Spd and the value Spc increase in the surface of the aluminum alloy 1000 when the aluminum alloy 1000 having the physical irregularity formed thereon is immersed into the phosphoric acid mixture, compared to a case where the aluminum alloy 1000 having the physical irregularity formed thereon is immersed into the phosphoric acid solution. Accordingly, it is identified that an unevenness count (the number of particles) on the surface of the aluminum alloy 1000 increases and the unevenness is finer, when the aluminum alloy 1000 having the physical irregularity formed thereon is immersed into the phosphoric acid mixture.

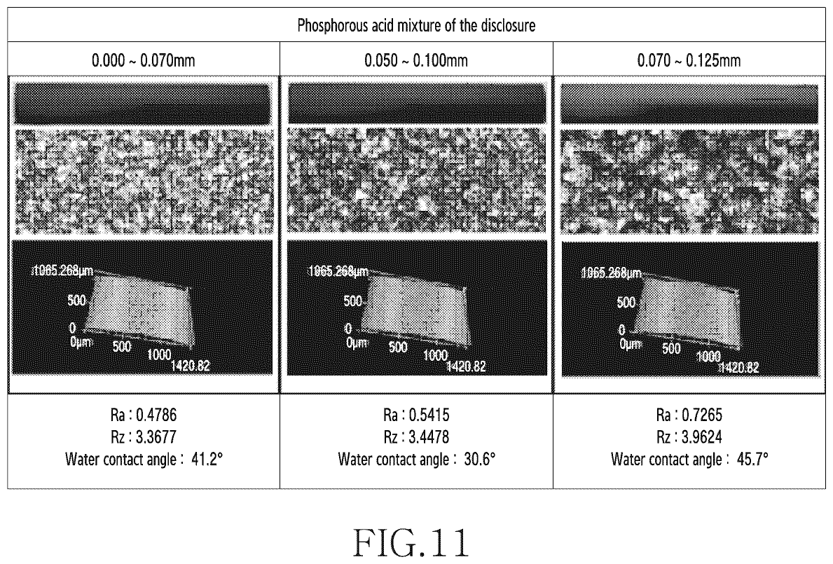

FIG. 11 is a diagram comparing a surface of an aluminum alloy on which a physical irregularity is formed by sand blasting using a different bead when the aluminum alloy is immersed into a phosphorous acid mixture according to various embodiments.

Referring to FIG. 11, when the aluminum alloy 1000 on which the physical irregularity is formed by sand blasting using a bead of 0.070 mm or less is immersed into the phosphorous acid mixture, a water contact angle of the oxidized aluminum alloy 1000 is measured to be 41.2°.

When the aluminum alloy 1000 on which the physical irregularity is formed by sand blasting using a bead of 0.050 to 0.100 mm is immersed into the phosphorous acid mixture, the water contact angle of the oxidized aluminum alloy 1000 is measured to be 30.6°.

When the aluminum alloy 1000 on which the physical irregularity is formed by sand blasting using a bead of 0.070 mm to 0.125 mm is immersed into the phosphorous acid mixture, the water contact angle of the oxidized aluminum alloy 1000 is measured to be 45.7°.

Referring to FIG. 11, when the aluminum alloy 1000 on which the physical irregularity is formed by sand blasting using a bead is immersed into the phosphorous acid mixture according to an embodiment of the disclosure, it is identified that the water contact angle of the oxidized aluminum alloy 1000 has a satisfactory value of about 30 to 50°. In particular, when the aluminum alloy 1000 on which the physical irregularity is formed by sand blasting using a bead of 0.050 mm to 0.100 mm is immersed into the phosphorous acid mixture, the water contact angle of the oxidized aluminum alloy 1000 has a lowest value, and when a size of the bead is large, such as 0.070 mm to 0.125 mm, the water contact angle tends to increase.

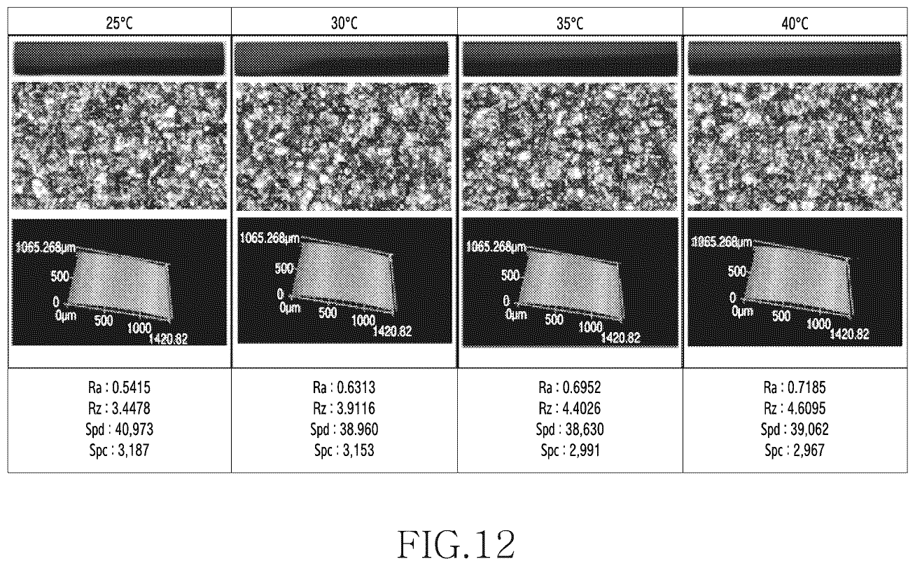

FIG. 12 is a diagram comparing a surface of an aluminum alloy having a physical irregularity formed thereon when the aluminum alloy is immersed into a phosphorous acid mixture of a different temperature according to various embodiments.

Referring to FIG. 12, when the aluminum alloy 1000 on which the physical irregularity is formed by the operation of FIG. 2 and FIG. 3 is immersed into the phosphorous acid mixture under the condition of 25° C., the anodized aluminum alloy 1000 is measured such that Ra is 0.5415, Rz is 3.4478, Spd is 40973, and Spc is 3187.

When the aluminum alloy 1000 on which the physical irregularity is formed by the operation of FIG. 2 and FIG. 3 is immersed into the phosphorous acid mixture under the condition of 30° C., the anodized aluminum alloy 1000 is measured such that Ra is 0.6313, Rz is 3.9116, Spd is 38960, and Spc is 3153.

When the aluminum alloy 1000 on which the physical irregularity is formed by the operation of FIG. 2 and FIG. 3 is immersed into the phosphorous acid mixture under the condition of 35° C., the anodized aluminum alloy 1000 is measured such that Ra is 0.6952, Rz is 4.4026, Spd is 38630, and Spc is 2991.

When the aluminum alloy 1000 on which the physical irregularity is formed by the operation of FIG. 2 and FIG. 3 is immersed into the phosphorous acid mixture under the condition of 45° C., the anodized aluminum alloy 1000 is measured such that Ra is 0.7185, Rz is 4.6095, Spd is 39062, and Spc is 2967.

When the aluminum alloy 1000 is immersed into the phosphorous acid mixture under the condition of 25° C. to 30° C., a separate cooling device is not required because an exothermic reaction caused by a chemical reaction is not significant, and a temperature rising device for heating is not required. However, when a great amount of aluminum alloys are treated for a long time, there may be a case where an immersion treatment is performed under the condition of 40° C. The values Ra and Rz of the anodized aluminum alloy 1000 tend to increase also in this case, but are maintained at satisfactory levels. It is identified that the values Spd and Spc are also at similar levels. Accordingly, when the aluminum alloy 1000 is immersed into the phosphorous acid mixture under the condition of 25° C. to 30° C. according to an embodiment of the disclosure, even if an unexpected situation occurs in which an immersion temperature increases, it is possible to manufacture the anodized aluminum alloy 1000 of a satisfactory level.

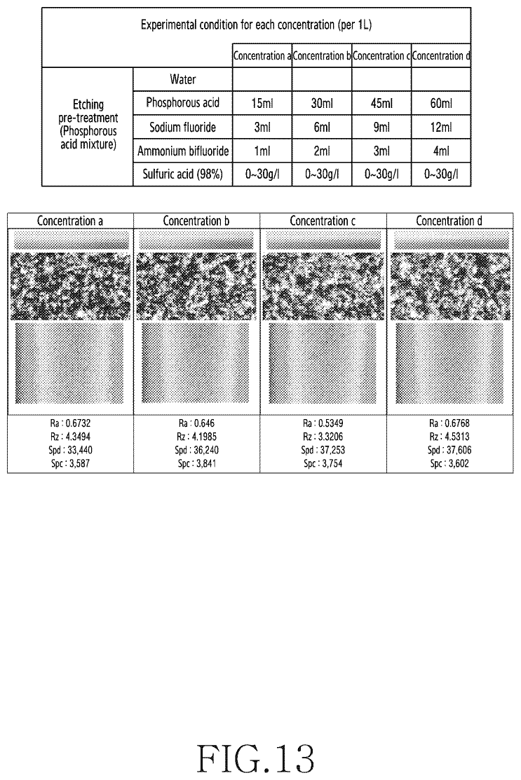

FIG. 13 is a diagram comparing a surface of an aluminum alloy having a physical irregularity formed thereon when the aluminum alloy is immersed into a phosphorous acid mixture of a different concentration according to various embodiments.

Referring to FIG. 13, when the aluminum alloy 1000 on which the physical irregularity is formed by the operation of FIG. 2 and FIG. 3 is immersed into phosphorous acid mixtures having respective concentrations a, b, c, and d, a surface property of the anodized aluminum alloy 1000 is measured.

The phosphorous acid mixture having the concentration a contains 15 ml of phosphorous acid, 3 ml of sodium fluoride, and 1 ml of ammonium bifluoride per 1 L of water. The phosphorous acid mixture having the concentration b contains 30 ml of phosphorous acid, 6 ml of sodium fluoride, and 2 ml of ammonium bifluoride per 1 L of water. The phosphorous acid mixture having the concentration c contains 45 ml of phosphorous acid, 9 ml of sodium fluoride, and 3 ml of ammonium bifluoride per 1 L of water. The phosphorous acid mixture having the concentration d contains 60 ml of phosphorous acid, 12 ml of sodium fluoride, and 4 ml of ammonium bifluoride per 1 L of water.

In addition, each of the phosphorous acid mixture having the concentration a, the phosphorous acid mixture having the concentration b, the phosphorous acid mixture having the concentration c, and the phosphorous acid mixture having the concentration d further contains 0 to 30 g/l of sulfuric acid (98%).

Referring to FIG. 13, even when the concentration of the phosphorous acid mixture is increased to the concentration a, the concentration b, the concentration c, and the concentration d within a range of 10 to 100 ml of phosphorous acid, 3 to 20 ml of sodium fluoride, and 1 to 10 ml of ammonium bifluoride per 1 L of water, appearance, particle density (Spd and Spc), and surface roughness values (Ra and Rz) of the anodized aluminum alloy 1000 are maintained at satisfactory levels.

Accordingly, considering a property of the aluminum alloy 1000, the concentration of the phosphorous acid mixture may be adjusted within the range of 10 to 100 ml of phosphorous acid, 3 to 20 ml of sodium fluoride, and 1 to 10 ml of ammonium bifluoride per 1 L of water.

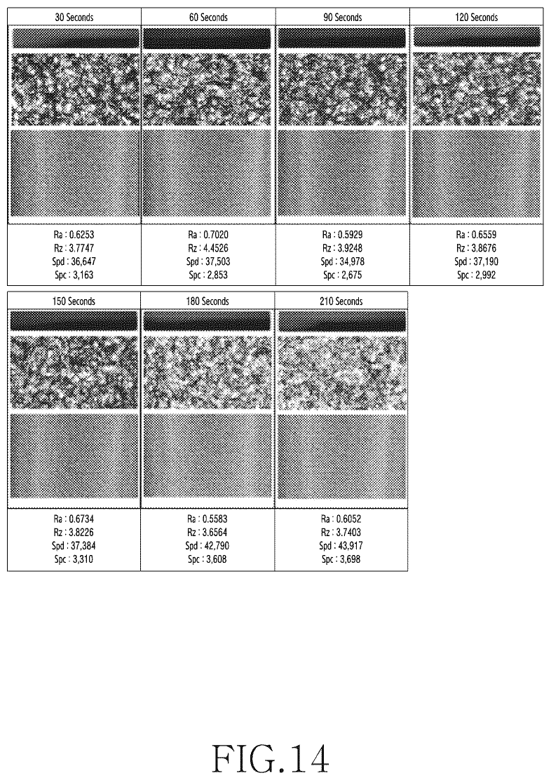

FIG. 14 is a diagram comparing a surface of an aluminum alloy having a physical irregularity formed thereon when the aluminum alloy is immersed into a phosphorous acid mixture for different times according to various embodiments.

Referring to FIG. 14, when the aluminum alloy 1000 on which the physical irregularity is formed by the operation of FIG. 2 and FIG. 3 is immersed into the phosphorous acid mixture for different immersion times (e.g., 30 seconds, 60 seconds, 90 seconds, 120 seconds, 150 seconds, 180 seconds, 210 seconds), a surface property of the anodized aluminum alloy 1000 is measured.

When the aluminum alloy 1000 having the physical irregularity formed thereon is immersed into the phosphorous acid mixture within a range of 30 to 210 seconds, surface roughness and particle density of the anodized aluminum alloy 1000 are maintained at satisfactory levels.

When the aluminum alloy 1000 having the physical irregularity formed thereon is immersed into the phosphorous acid mixture within a range of 30 to 210 seconds, there is little change in the values Ra and Rz, but the particle density tends to increase from about 180 seconds.

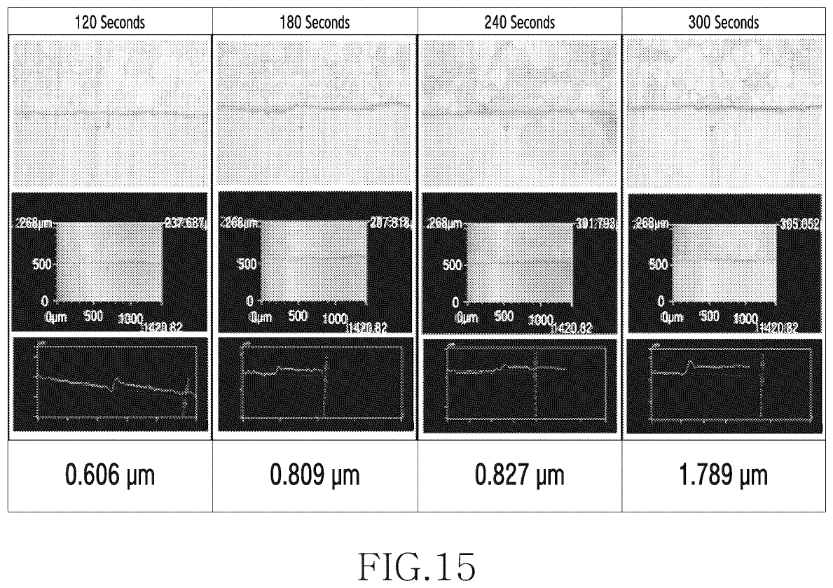

FIG. 15 is a diagram comparing an etching amount of an aluminum alloy having a physical irregularity formed thereon when the aluminum alloy is immersed into a phosphorous acid mixture for a different time according to various embodiments.

Referring to FIG. 15, when the aluminum alloy 1000 on which the physical irregularity is formed by the operation of FIG. 2 and FIG. 3 is immersed into the phosphorous acid mixture for different immersion times (e.g., 120 seconds, 180 seconds, 240 seconds, and 300 seconds), the etching amount of the aluminum alloy 1000 increases in proportion to the immersion time for which it is immersed into the phosphorous acid mixture. Accordingly, when there is a need to adjust a size of the aluminum alloy 1000 to be manufactured, the immersion time may be set in accordance with the etching amount of the aluminum alloy 1000.

According to an embodiment of the disclosure, the anodized aluminum alloy 1000 may include an aluminum alloy layer and an anodizing layer. A cross-section of the anodized aluminum alloy 1000 of FIG. 2 and FIG. 3 may be divided into the aluminum alloy layer and the anodizing layer.

When a 6000-series aluminum alloy is anodized, the aluminum alloy layer contains the 6000-series aluminum alloy, and when a 7000-series aluminum alloy is anodized, the aluminum alloy layer contains the 7000-series aluminum alloy.

Since the aluminum alloy 1000 having the physical irregularity formed thereon is immersed into the phosphorous acid mixture at a designated temperature for a designated treatment time, an etching reaction occurs more actively in a peak portion than in a concave portion of the physical irregularity of the aluminum alloy 1000, and the surface of the aluminum alloy 1000 may be refined while the physical irregularity of the aluminum alloy 1000 is maintained.

The anodizing layer may be formed by anodizing the surface of the aluminum alloy 1000 of which the irregularity of the surface is refined by the phosphorous acid mixture. The anodizing layer may be an oxide layer formed by oxidizing the aluminum alloy 1000. The anodizing layer contains fine pores, and air or moisture may be prevented/reduced from entering the pores through a sealing operation.

According to an embodiment, a coloring operation may be added prior to the sealing operation. When the coloring operation is added, a dye may be prevented or blocked from escaping from pores through the sealing operation.

The anodizing layer may be a surface layer exposed to the outside of the aluminum alloy of which the surface is treated by including an anodizing treatment. The anodizing layer may have a surface texture of fine particles, and may have a water contact angle of 30° to 50°. In addition, the surface of the anodizing layer may have a surface roughness value of Ra 1.00 μm or less and Rz 8.00 μm or less, and the surface of the anodizing layer may have a particle density (spd) of 30,000/mm² to 50,000/mm². In addition, the surface of the anodizing layer may have a low gloss value of 15 GU or less.

A cross-section of the anodized aluminum alloy according to an embodiment of the disclosure may have an aluminum alloy layer and an anodizing layer. The anodizing layer may be an anodizing layer which has undergone the sealing operation, or an anodizing layer to which the coloring operation and the sealing operation have been applied. The anodized aluminum alloy 1000 may not have a coating layer having a component other than the aluminum alloy and aluminum oxide.

Due to hydrophilicity of the surface of the aluminum alloy 1000 having the physical irregularity immersed into the phosphorous acid mixture according to an embodiment of the disclosure, cleaning of foreign substances and residual acid on the surface is facilitated when cleaning is underway during the anodizing operation. In addition, since wettability of the surface is improved in the coloring operation which uses an aqueous method of dissolving a dye in water, a phenomenon in which the surface is unevenly colored may be prevented/reduced. In addition, a surface irregularity is refined by increasing the particle density which determines the texture of the surface, resulting in soft tactility having slipperiness and a low gloss of 10 GU or less.

According to an embodiment of the disclosure, the hydrophilic surface is realized by immersing the aluminum alloy 1000 having the physical irregularity formed thereon into the phosphorous acid mixture. Accordingly, visibility of surface contamination of the aluminum alloy 1000 is reduced, and anti-fingerprint and anti-contamination properties of the surface of the aluminum alloy 1000 are secured. Therefore, an aluminum exterior material having various colors, uniform and fine particle texture, and slipperiness may be prepared.

The effects achievable from this disclosure are not limited to those explicitly mentioned above. Other effects, not specifically mentioned, can be clearly understood by a person skilled in the art to which this disclosure pertains, based on the descriptions.

The processes described in this disclosure are merely example embodiments and do not limit the scope of this disclosure in any way. For brevity, descriptions of conventional processes for anodizing aluminum alloys may be omitted.

Furthermore, in this disclosure, the phrase “comprising at least one of a, b, or c” may refer, for example, to: including only a, including only b, including only c, including both a and b, including both b and c, including both a and c, or including all of a, b, and c.

The above description of the disclosure is for illustrative purposes only, and those skilled in the art will understand that the technical idea and essential features of this disclosure can be easily modified into other specific forms without altering the spirit of the disclosure. Thus, the various embodiments described above should be understood as illustrative in all respects and not restrictive. For example, components described as singular may be implemented in a distributed form, and components described as distributed may be implemented in a combined form.

The scope of this disclosure includes the claims set forth below, and is not limited by the detailed description. All modifications or variations derived from the meaning, scope, and equivalents of the claims should be interpreted as falling within the scope of this disclosure.

What is claimed is:

1. A method of treating a surface of an aluminum alloy, comprising:
processing the aluminum alloy in a designated shape;
forming an irregularity physically on the surface of the aluminum alloy processed in the designated shape;
immersing the aluminum alloy having the irregularity formed thereon into a phosphorous acid mixture containing phosphorous acid, sodium fluoride, and ammonium bifluoride with a designated mixing ratio; and
anodizing the immersed aluminum alloy,
wherein the phosphorous acid mixture contains 15 to 100 ml of the phosphorous acid, 3 to 20 ml of the sodium fluoride, and 1 to 10 ml of the ammonium bifluoride per 1 L of water.

2. The method of claim 1, wherein the forming of the irregularity physically includes forming, on the processed aluminum alloy, the irregularity having a surface roughness value of Ra 2.00 μm or less and Rz 15.00 μm or less using a sand blasting technique.

3. The method of claim 2, wherein the forming of the irregularity physically includes forming the irregularity by spraying a bead having a size of 0.20 mm or less on the processed aluminum alloy at a pressure of 2 to 5 bar.

4. The method of claim 3,
wherein the bead includes a ball-type bead and a grit-type bead, and
wherein a defect on the processed aluminum alloy and a mark caused by a processing tool are removed by spraying the bead.

5. The method of claim 1, wherein a sparingly soluble salt produced by the phosphorous acid contained in the phosphorous acid mixture and the aluminum alloy having the irregularity formed thereon is accumulated in a concave portion of the irregularity, and a portion corresponding to the concave portion is blocked from etching in the aluminum alloy on which the irregularity is formed by the sparingly soluble salt accommodated in the concave portion.

6. The method of claim 1, wherein the immersing of the aluminum alloy includes immersing the aluminum alloy into the phosphorous acid mixture at a room temperature of about 25° C. to 30° C.

7. The method of claim 6, wherein the immersing of the aluminum alloy includes immersing the aluminum alloy into the phosphorous acid mixture for 30 seconds to 210 seconds.

8. The method of claim 1, wherein the phosphorous acid mixture contains 0 to 30 g/L of sulfuric acid per 1 L of water.

9. The method of claim 1, wherein the surface of the anodized aluminum alloy has a hydrophilic property having a water contact angle of 30 to 50°.

10. The method of claim 1, wherein the surface of the anodized aluminum alloy has a surface roughness value of Ra of 1.00 μm or less and Rz of 8.00 μm or less, and a particle density (spd) of 30,000/mm² to 50,000/mm².

11. The method of claim 1, wherein the aluminum alloy contains a 6000-series aluminum alloy and a 7000-series aluminum alloy.

12. A surface-treated aluminum alloy comprising:
an anodizing layer produced by forming an irregularity physically on a surface of an aluminum alloy, immersing the aluminum alloy having the irregularity formed thereon into a phosphorous acid mixture, and performing anodizing thereon, and which is exposed to the outside of the anodized aluminum alloy; and
an aluminum alloy layer located below the anodizing layer,
wherein the surface of the anodizing layer has a water contact angle of 30° to 50° and a surface roughness value of Ra 1.00 μm or less and Rz 8.00 μm or less.

13. The surface-treated aluminum alloy of claim 12, wherein the surface of the anodizing layer has a particle density (spd) of 30,000/mm² to 50,000/mm².

14. The surface-treated aluminum alloy of claim 12, wherein the surface of the anodizing layer has a gloss value of 15 GU or less.

15. The surface-treated aluminum alloy of claim 12, wherein the phosphorous acid mixture contains 15 to 100 ml of the phosphorous acid, 3 to 20 ml of the sodium fluoride, and 1 to 10 ml of the ammonium bifluoride per 1 L of water.
